(19) United States
(12) Patent Application Publication
(10) Pub. No.: US 2024/0184963 A1
(43) Pub. Date: Jun. 6, 2024

(54) CIRCUIT DESIGN UPDATES USING REINFORCED LEARNING LOOP

(71) Applicant: International Business Machines Corporation, Armonk, NY (US)

(72) Inventors: Victor N. KRAVETS, Bangalore (IN); Gi-Joon NAM, Chappaqua, NY (US); Alexey Y. LVOV, Congers, NY (US); Ashish JAITLY, Bangalore (IN)

(21) Appl. No.: 18/061,368

(22) Filed: Dec. 2, 2022

(51) Int. Cl. G06F 30/33

(52) U.S. Cl. CPC G06F 30/33

(57) ABSTRACT

A method includes receiving a circuit design and a specification for the circuit design and determining a first hypothesized change to the circuit design. Making the first hypothesized change to the circuit design produces a first changed circuit design. The method also includes determining a first counterexample input that causes the first changed circuit design to produce an output that departs from the specification and determining a second hypothesized change to the circuit design based at least in part on the first hypothesized change. Making the second hypothesized change to the circuit design produces a second changed circuit design. The method further includes, in response to determining that the second changed circuit design has no counterexample input that causes the second changed circuit design to produce an output that departs from the specification, making the second hypothesized change to the circuit design.

### BACKGROUND

The present invention relates to the design of electronic circuits, and more specifically, to updating electronic circuit designs using reinforced learning.

### SUMMARY

According to an embodiment, a method includes receiving a circuit design and a specification for the circuit design and determining a first hypothesized change to the circuit design based at least in part on the circuit design and the specification. Making the first hypothesized change to the circuit design produces a first changed circuit design. The method also includes determining a first counterexample input that causes the first changed circuit design to produce an output that departs from the specification and determining a second hypothesized change to the circuit design based at least in part on the first hypothesized change. Making the second hypothesized change to the circuit design produces a second changed circuit design. The method further includes, in response to determining that the second changed circuit design has no counterexample input that causes the second changed circuit design to produce an output that departs from the specification, making the second hypothesized change to the circuit design. Other embodiments include a system that performs this method and a non-transitory computer readable medium storing instructions that, when executed, cause a processor to perform this method.

### BRIEF DESCRIPTION OF THE DRAWINGS

FIG. 1A illustrates an example electronic circuit design process.

FIG. 1B illustrates an example electronic circuit revision process.

FIG. 2 illustrates an example system for updating an electronic circuit design.

FIG. 3 illustrates an example process for updating an electronic circuit design performed in the system of FIG. 2.

FIG. 4 illustrates an example process for updating an electronic circuit design performed in the system of FIG. 2.

FIGS. 5 through 11 illustrate an example of updating an electronic circuit design performed in the system of FIG. 2.

FIG. 12 is a flowchart of an example method performed in the system of FIG. 2.

FIG. 13 illustrates an example computing environment.

### DETAILED DESCRIPTION

Electronic circuits go through a lengthy design process before the electronic circuits are fabricated. This design process involves many different steps or stages, usually involving many different teams of engineers. Revisions to an electronic circuit design frequently occur during the design process. These revisions often result from a newly discovered bug or an evolved design functionality. In the early stages of development, revising or updating the electronic circuit design is relatively simple and an accepted norm. As the design reaches more advanced development stages, however, making revisions and updates becomes a more challenging task. For example, these revisions and updates may break the attained quality of the circuit design or may be too costly (e.g., if mask re-spinning is needed). The conventional solution is to update the circuit design incrementally, with a minor intrusion to its attained structure. The task of finding the non-intrusive revision or update to the circuit design to comply with a new or revised specification may be challenging and time consuming.

The present disclosure contemplates a system that determines the incremental changes to a circuit design to satisfy a new or revised specification. Generally, the system uses a reinforced learning loop to generate hypothesized changes to the circuit design. These hypotheses are then proven or disproven through discovery of counterexample inputs that would cause the circuit design with the hypothesized changes to not satisfy the new or revised specification. These counterexamples are then used in the learning loop to refine the hypotheses until the learning loop produces a hypothesis with no counterexample inputs. This hypothesis is then determined to be the incremental update to the circuit design and is made to the circuit design such that the circuit design satisfies the new or revised specification. In some embodiments, the system searches a provably complete domain (e.g., stated as a closed form expression) of functionally possible changes or updates and provides better solutions relative to known approaches. Additionally, the system's approach is scalable to larger circuit designs.

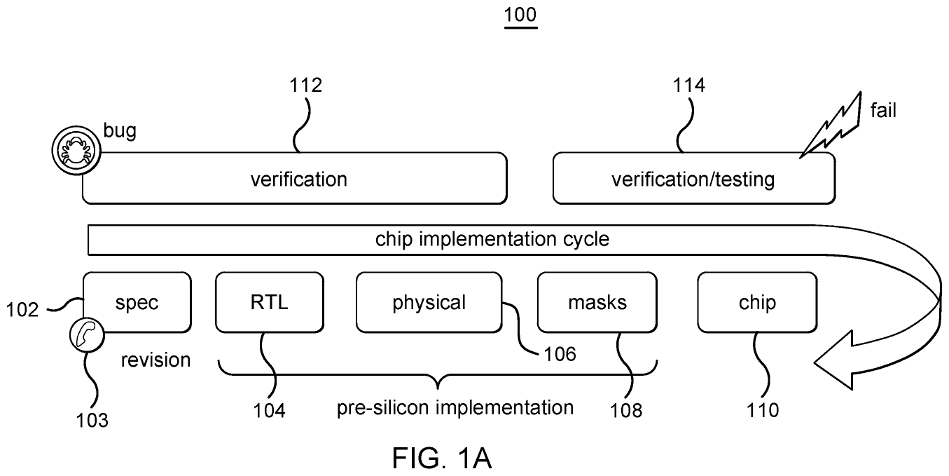

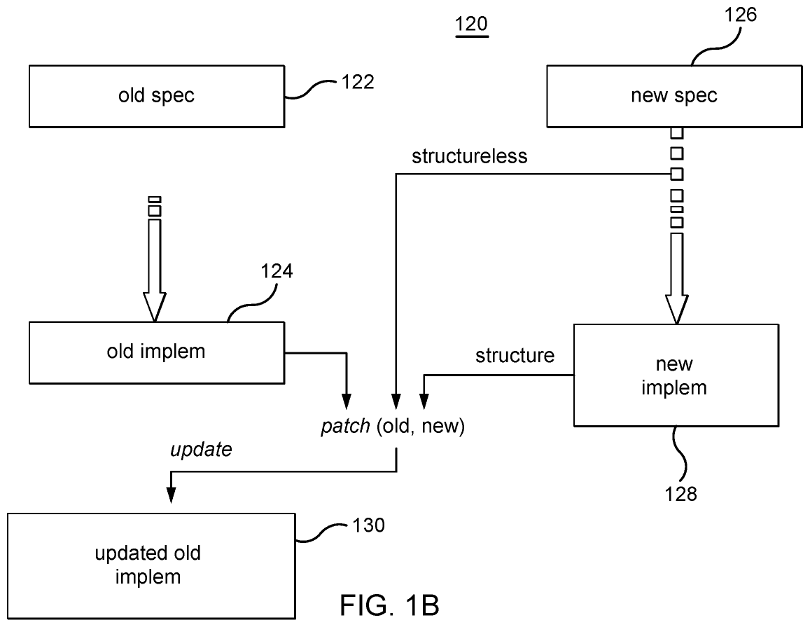

FIG. 1A illustrates an example electronic circuit design process 100. As see in FIG. 1, the process 100 may begin with a specification stage 102. At the specification stage 102, a circuit design is described according to a specification. For example, the specification may explain the structures of the circuit and the expected behavior of the circuit. The specification may specify the inputs to the circuit and the expected outputs for certain input values to the circuit. During the design process 100, one or more revisions 103 may be made to the specification. When the revisions 103 are made at the specification stage 102, the impact on the design process 100 may be minimal. However, if the revisions 103 are made at later stages of the design process 100, then it may become more difficult and more costly to make the revisions 103.

After the circuit design is described in a specification, the design process 100 continues to the register transfer level (RTL) stage 104. During the RTL stage 104, the circuit design is taken from the specification and described in a hardware description language (HDL). The circuit design may be described with a focus on the registers and combinational logic in the circuit design. The flow of signals between the registers and combinational logic may also be described at the RTL stage 104.

During the physical synthesis stage 106, the RTL description of the circuit design is analyzed to generate a physical design for the circuit. For example, the components of the circuit design specified in the RTL description may be analyzed to determine the logic elements to be retrieved from cell libraries. These logic elements are then placed and interconnected in a physical circuit design. During the physical synthesis stage 106, the timing, area, and power of the physical design may be optimized.

After the physical implementation of the circuit is generated, the design process 100 may continue to the mask stage 108. During the mask stage 108, a physical mask for the circuit design may be designed or created. The mask design or the mask data may be subsequently used to generate photomasks that are used during lithography. These masks may represent the circuit design in terms of plainer geometric shapes that correspond to the patterns of metal oxide or semiconductor layers that make up the circuit design.

After the masks are created, the design process 100 continues to the chip fabrication stage 110. During the chip fabrication stage 110, the integrated circuit or the chip is fabricated using the generated masks. During the lithography step of the chip fabrication stage 110, the masks are used to pattern the light onto a wafer to create the integrated circuit according to the circuit design.

Various tests may be run during each stage of the design process 100. For example, during the specification stage 102, the RTL stage 104, and the physical synthesis stage 106, one or more verification tests 112 may be performed to detect bugs in the circuit design. When bugs are detected, one or more revisions 103 may be made to the specification to correct the bug. During the mask stage 108 and the chip fabrication stage 110, one or more validation tests 114 may be executed against the circuit design or the generated mask. The validation test 114 may test the function of the circuit or the quality of the fabricated chip. The validation test 114 may detect whether there are failures in the mask or the fabricated chip. If a failure is detected, the fabricated chip or the mask may need to be remade. The bugs or failures could arise from errors in the circuit design, revisions 103 to the specification, variability in the modeling optimism, or unforeseen events.

FIG. 1B illustrates an example electronic circuit revision process 120. During the revision process 120, one or more revisions are made to a specification to change a circuit design. The revision process 120 begins with an old specification 122. The old specification 122 may describe a circuit design. For example, the old specification 122 may describe the structure and expected behavior of the circuit design. An old implementation 124 for the circuit design is generated from the old specification 122. For example, the old implementation 124 may include an RTL description or physical synthesis description of a circuit design generated from the old specification 122.

A new specification 126 may be generated that includes revisions or changes to the old specification 122. These revisions or changes may be made to correct bugs discovered in the circuit design or the old implementation 124. A new implementation 128 is generated from the new specification 126. The new implementation 128 may include a new design for the old circuit design.

The new specification 126 and the new implementation 128 may be analyzed to determine an update or change to be made to the old implementation 124. Making the update or change produces an updated old implementation 130. As a result the updated old implementation 130 may satisfy the new specification 126. The process of determining the update or change to the old implementation 124 based on the new specification 126 or the new implementation 128 may be a time consuming and costly process, depending on when the new specification 126 was introduced. The later in the chip design process the new specification 126 is introduced, the more costly the update process may be. In certain instances, it may be desirable to determine the update or change that causes the least disruption to an existing implementation. Moreover, structureless updates may simplify the update process by removing the need for pre-compilation of the new specification 126 to match the structure of the old implementation 130.

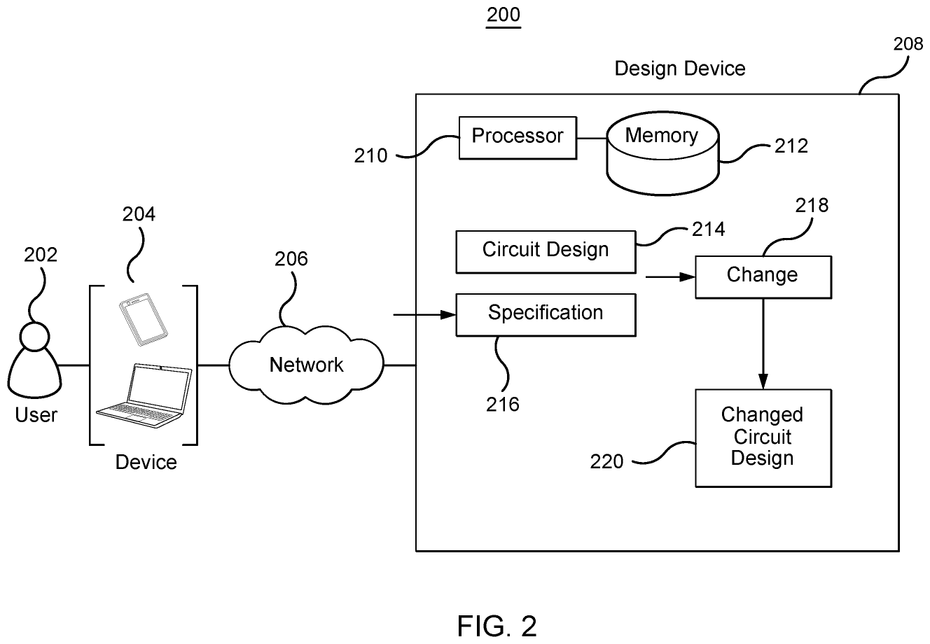

FIG. 2 illustrates an example system 200 for updating an electronic circuit design. As seen in FIG. 2, the system 200 includes one or more devices 204, a network 206, and a design device 208. Generally, the system 200 uses a reinforced learning loop to generate hypothesized changes to a circuit design. These hypotheses are then proven or disproven through discovery of counterexample inputs that would cause the circuit design with the hypothesized changes to not satisfy a new or revised specification. These counterexamples are then used in the learning loop to refine the hypotheses until the learning loop produces a hypothesis with no counterexample inputs. This hypothesis is then determined to be the incremental update to the circuit design and is made to the circuit design such that the circuit design satisfies the new or revised specification.

A user 202 uses a device 204 to initiate or control the circuit design process. For example, the user 202 may use the device 204 to issue instructions to the design device 208. These instructions may cause the design device 208 to initiate the learning loop to discover an incremental change to a circuit design. The device 204 is any suitable device for communicating with components of the system 200 over the network 206. As an example and not by way of limitation, the device 204 may be a computer, a laptop, a wireless or cellular telephone, an electronic notebook, a personal digital assistant, a tablet, or any other device capable of receiving, processing, storing, or communicating information with other components of the system 200. The device 204 may be a wearable device such as a virtual reality or augmented reality headset, a smart watch, or smart glasses. The device 204 may also include a user interface, such as a display, a microphone, keypad, or other appropriate terminal equipment usable by the user 102. The device 204 may include a hardware processor, memory, or circuitry configured to perform any of the functions or actions of the device 204 described herein. For example, a software application designed using software code may be stored in the memory and executed by the processor to perform the functions of the device 204.

The network 206 is any suitable network operable to facilitate communication between the components of the system 200. The network 206 may include any interconnecting system capable of transmitting audio, video, signals, data, messages, or any combination of the preceding. The network 206 may include all or a portion of a public switched telephone network (PSTN), a public or private data network, a local area network (LAN), a metropolitan area network (MAN), a wide area network (WAN), a local, regional, or global communication or computer network, such as the Internet, a wireline or wireless network, an enterprise intranet, or any other suitable communication link, including combinations thereof, operable to facilitate communication between the components.

The design device 208 uses a reinforced learning loop to discover incremental changes to be made to a circuit design. As seen in FIG. 2, the design device 208 includes a processor 210 and a memory 212 that perform the actions or functions of the design device 208 described herein.

The processor 210 is any electronic circuitry, including, but not limited to one or a combination of microprocessors, microcontrollers, application specific integrated circuits (ASIC), application specific instruction set processor (ASIP), and/or state machines, that communicatively couples to memory 212 and controls the operation of the design device 208. The processor 210 may be 8-bit, 16-bit, 32-bit, 64-bit or of any other suitable architecture. The processor 210 may include an arithmetic logic unit (ALU) for performing arithmetic and logic operations, processor registers that supply operands to the ALU and store the results of ALU operations, and a control unit that fetches instructions from memory and executes them by directing the coordinated operations of the ALU, registers and other components. The processor 210 may include other hardware that operates software to control and process information. The processor 210 executes software stored on the memory 212 to perform any of the functions described herein. The processor 210 controls the operation and administration of the design device 208by processing information (e.g., information received from the devices 204, network 206, and memory 212). The processor 210 is not limited to a single processing device and may encompass multiple processing devices.

The memory 212 may store, either permanently or temporarily, data, operational software, or other information for the processor 210. The memory 212 may include any one or a combination of volatile or non-volatile local or remote devices suitable for storing information. For example, the memory 212 may include random access memory (RAM), read only memory (ROM), magnetic storage devices, optical storage devices, or any other suitable information storage device or a combination of these devices. The software represents any suitable set of instructions, logic, or code embodied in a computer-readable storage medium. For example, the software may be embodied in the memory 212, a disk, a CD, or a flash drive. In particular embodiments, the software may include an application executable by the processor 210 to perform one or more of the functions described herein.

The design device 208 receives a circuit design 214. For example, the user 202 may use the device 204 to create the circuit design 214. In some embodiments, the design device 208 may have created the circuit design 214 using instructions from the user 202. The circuit design 214 may have been created to satisfy a specification that describes the components and expected behavior of the circuit design 214. During the design process, the user 202 may revise or change the specification. For example, the user 202 may revise the specification to correct bugs or other unintended behavior of the circuit design 214 discovered during the design process. Revising the specification produces a revised specification 216.

The user 202 may use the device 204 to communicate the revised specification 216 to the design device 208. The specification 216 may specify the elements of the circuit design 214 and the expected behavior of the circuit design 214. For example, the specification 216 may specify the inputs of the circuit design 214 and the expected outputs of the circuit design 214 to certain input values. The circuit design 214 may not satisfy the constraints specified in the revised specification 216. The design device 208 uses a reinforced learning loop to determine a change 218 that should be made to the circuit design 214 so that the circuit design 214 satisfies the revised specification 216.

Generally, the design device 208 uses the reinforced learning loop to generate hypothesized changes to the circuit design 214. The design device 208 may test these hypothesized changes to see if there exists a counterexample input that causes the circuit design 214 with the hypothesized changes to not satisfy the revised specification 216. The design device 208 may update or revise these hypothesized changes until no counterexample input is discovered. After the design device 208 determines a hypothesized change that does not have a counterexample input, the design device 208 may make that hypothesized change to the circuit design 214 to produce a changed circuit design 220. The changed circuit design 220 may include an update to the circuit design 214 so that the changed circuit design 220 satisfies the new specification 216. In certain embodiments, by using the reinforced learning loop, the design device 208 determines the changed circuit design 220 more quickly than conventional systems that incrementally update the circuit design 214 to satisfy a revised specification 216.

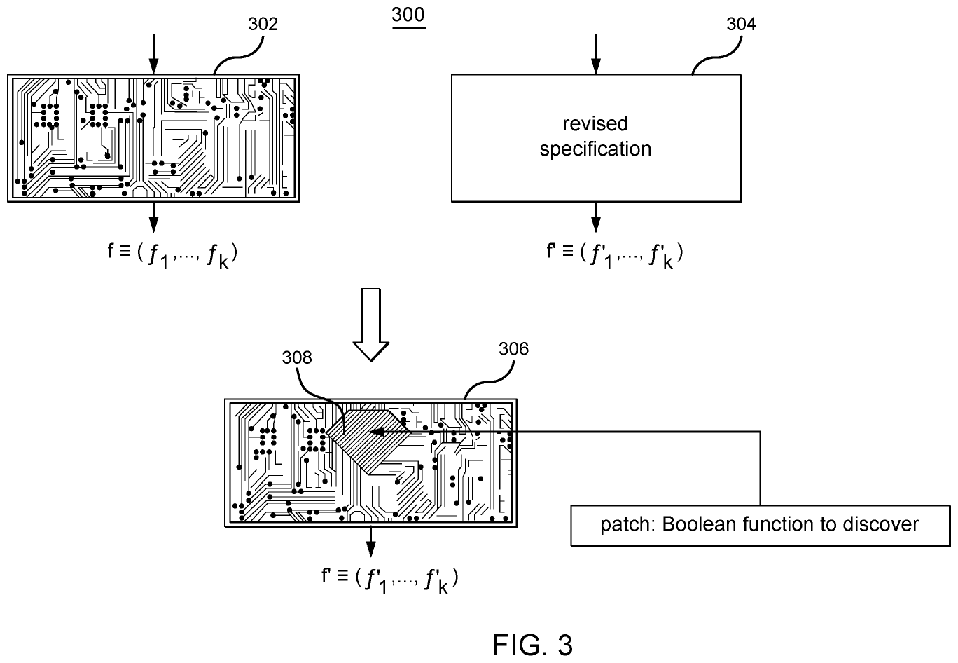

FIG. 3 illustrates an example process 300 for updating an electronic circuit design performed in the system 200 of FIG. 2. As seen in FIG. 3, the process 300 begins with a circuit design 302. The circuit design 302 may include a specification of the circuit design 302. The specification specifies one or more functions of the circuit design 302 represented by the vector f. The vector f indicates multiple functions f₁ through fₖ.

The revised specification 304 may indicate one or more changes to the behavior of the circuit design 302. For example, the revised specification 304 may indicate one or more changes to the functions specified in the specification. In the example of FIG. 3, the revised specification 304 indicates one or more changed functions indicated by the vector f′. The vector f′ includes one or more changed functions f′₁ through f′ₖ. In some instances, not every function indicated in the vector f′ includes a change relative to the corresponding function in the vector f. Only some of the functions in the vector f′ may include changes.

The design device 208 analyzes the circuit design 302 and the revised specification 304 to determine an updated circuit design 306. As seen in FIG. 3, the updated circuit design 306 includes one or more changes 308 that are made to the circuit design 302. These changes 308 may be applied to the circuit design 302 by a patch. The patch may include the one or more changes 308 to be made to the circuit design 302. The rectification problems asks to rectify the circuit design 302 and the vector f to meet the revised specification 304 and the vector f′. In some embodiments, the design device 208 determines the patch by analyzing one or more Boolean function representations of the circuit design 302. The design device 208 uses the reinforced learning loop to analyze the Boolean function representations to determine the patch. After the patch has been applied and the changes 308 are made to the circuit design 302, the updated circuit design 306 satisfies the revised specification 304. Specifically, the updated circuit design 306 performs the functions indicated in the vector f′.

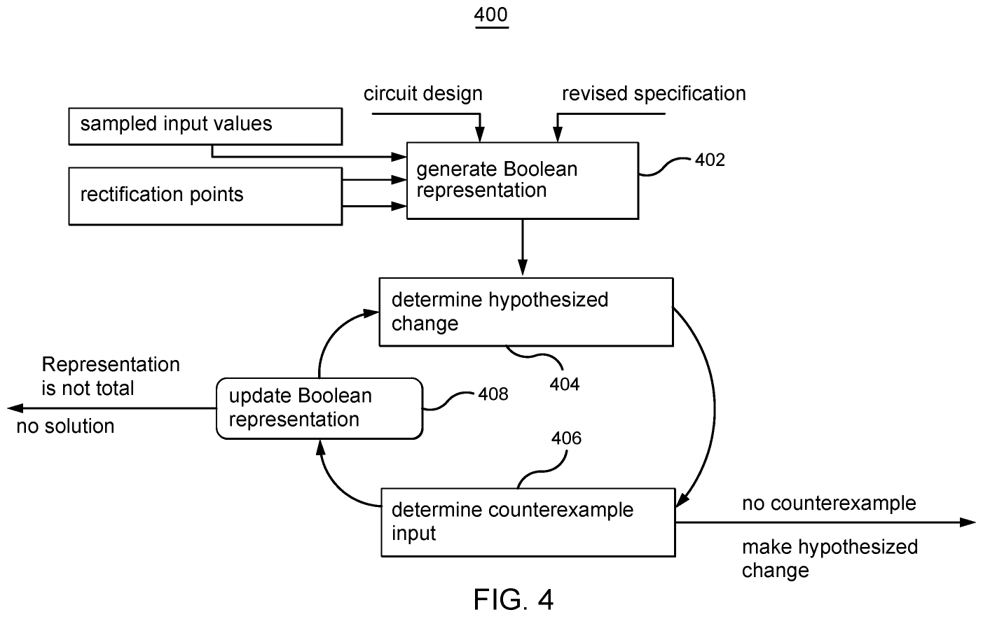

FIG. 4 illustrates an example process 400 for updating an electronic circuit design performed in the system 200 of FIG. 2. In certain embodiments, the design device 208 performs the process 400. By performing the process 400, the design device 208 determines a change to be made to a circuit design.

The design device 208 begins by receiving a circuit design and a revised specification that indicates a vector f′. The design device 208 also receives rectification points in the circuit design. The rectification points may be locations in the circuit design where changes may be made. The design device 208 may also receive sampled input values. These sampled input values may be input values that cause the circuit design to deviate from the functionality specified in the revised specification. The design device 208 then generates a Boolean representation in block 402. The design device 208 may use the circuit design, the revised specification, the rectification points, and the sampled input values to generate the Boolean representation. In some embodiments, the Boolean representation may indicate a hypothesis space from which a hypothesized change may be determined.

The design device 208 analyzes the Boolean representation to determine a hypothesized change in block 404. For example, the design device 208 analyze the Boolean representation to determine relevant and irrelevant signals in the circuit design. The design device 208 may abstract the irrelevant signals to reduce non-determinism and to yield a hypothesized change.

In block 406, the design device determines whether there are counterexample inputs that would cause the circuit design with the hypothesized change to not satisfy the revised specification. If the design device 208 discovers a counterexample input, then the design device 208 may determine that the hypothesized change should not be made to the circuit design. If the design device 208 discovers that there are no counterexample inputs, then the design device 208 may determine that the hypothesized change should be made to the circuit design. The design device 208 may be trained to reward the discovery of counterexample inputs so that the design device 208 is incentivized to discover counterexample inputs in the block 406.

The design device 208 uses the discovered counterexample inputs to update the Boolean representation in block 408. For example, the design device 208 may remove disproven hypothesized changes from the hypothesis space indicated by the Boolean representation. If the design device 208 discovers that the Boolean representation is not total, then the design device 208 may determine that no solution exists and that no change may be made to the circuit design that will satisfy the revised specification. For example, if the hypothesis space is empty, then no solution may exist. After updating the Boolean representation, the reinforced learning loop begins again with the design device 208 analyzing the updated Boolean representation to generate another hypothesis. The learning loop continues until the design device 208 determines that a hypothesized change causes the circuit design to have no counterexample inputs.

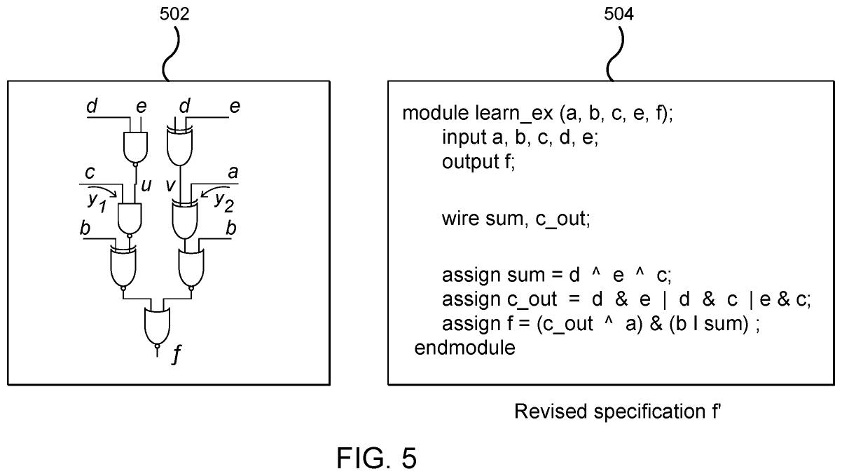

FIGS. 5 through 11 illustrate an example of updating an electronic circuit design performed in the system 200 of FIG. 2. In particular embodiments, the design device 208 performs the example process shown in FIGS. 5 through 11. As seen in FIG. 5, the process begins with a circuit design 502. The circuit design 502 includes a series of logic gates receiving various input signals at input ports. The input signals are labeled a, b, c, d, and c. The series of logic gates also produce an output signal labeled f. There are two intermediate signals in the circuit design labeled u and V. Additionally, the design device 208 is provided with the rectification points labeled y₁ and y₂. The design device 208 may use the reinforced learning loop to determine any changes that may be made to the circuit design at the rectification points y₁ and y₂.

The design device 208 also receives a revised specification 504. The revised specification 504 indicates the inputs and outputs for the circuit design 502. Additionally, the revised specification 504 indicates the expected behavior of the circuit design 502. The expected behavior indicated by the revised specification 504 may differ from the behavior of the circuit design 502. The design device 208 uses the reinforced learning loop to discover changes that may be made to the circuit design 502 at the rectification points y₁ and y₂ to satisfy the behavior indicated in the revised specification 504.

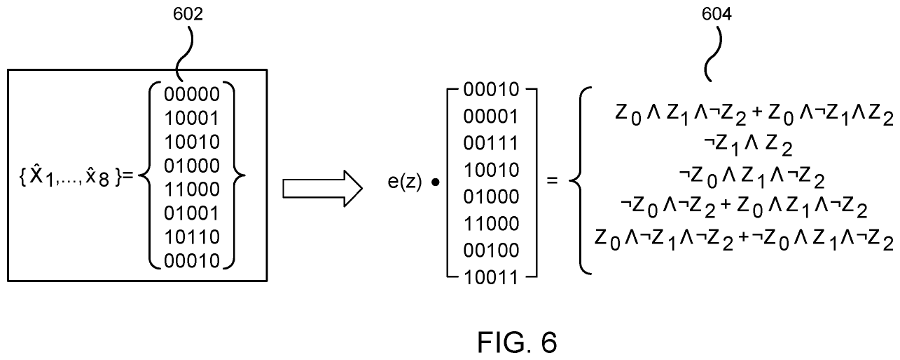

The design device 208 begins by generating the input samples to the circuit design 502 that would cause the circuit design 502 to deviate from the revised specification 504. In the example of FIG. 6, the design device 208 determines the input samples 602 that cause the circuit design 502 to deviate from the new specification 504. For example, the input samples 602 indicate that when all the input values to the circuit design 502 are logic 0 (e.g., a, b, c, d, and e are 0), the circuit design 502 deviates from the expected behavior indicated in the new specification 504. The input samples 602 also indicate the other seven combinations of input values of a, b, c, d, and e that cause the circuit design 502 to deviate from the revised specification 504.

The design device 208 then converts or transforms the input samples 602 to a Boolean representation. In the example of FIG. 6, three Boolean values Z₀, Z₁, and Z₂ are used to represent the eight input samples 602. For example, each of the eight input samples 602 may be assigned to a distinct combination of the three Boolean values Z₀, Z₁, and Z₂. The design device 208 then determines Boolean expressions using Z₀, Z₁, and Z₂ that express when the circuit design 502 deviates from the new specification 504. In the example of FIG. 6, the Boolean representation includes five Boolean expressions 604. When the values of Z₀, Z₁, and Z₂ cause any of the Boolean expressions 604 to return true, the circuit design 502 deviates from the revised specification 504. As seen in FIG. 6, there are five Boolean expressions 604 that capture the eight sampled input values 602.

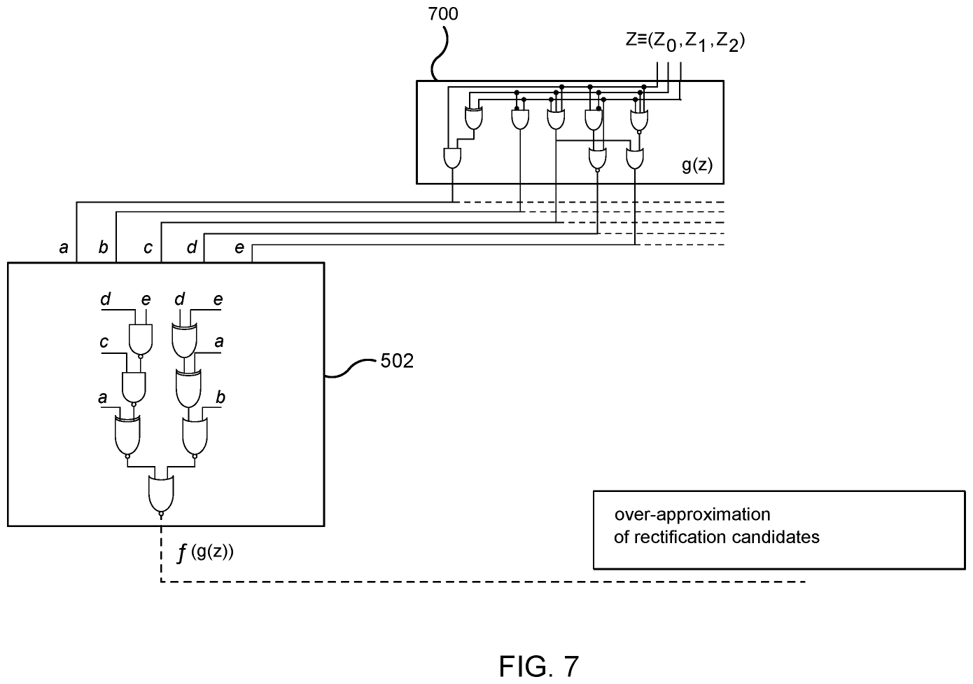

FIG. 7 shows a logic circuit representation 700 of the Boolean representation. As seen in FIG. 7, the logic circuit representation 700 takes the three Boolean values Z₀, Z₁, and Z₂ as inputs and then outputs the input signals to the circuit design 502. The design device 208 analyzes the logic circuit representation 700 to determine the hypothesis space. The hypothesis space includes various rectification or change candidates for the circuit design 502. In some embodiments, the design device 208 generates an over approximation of the rectification candidates.

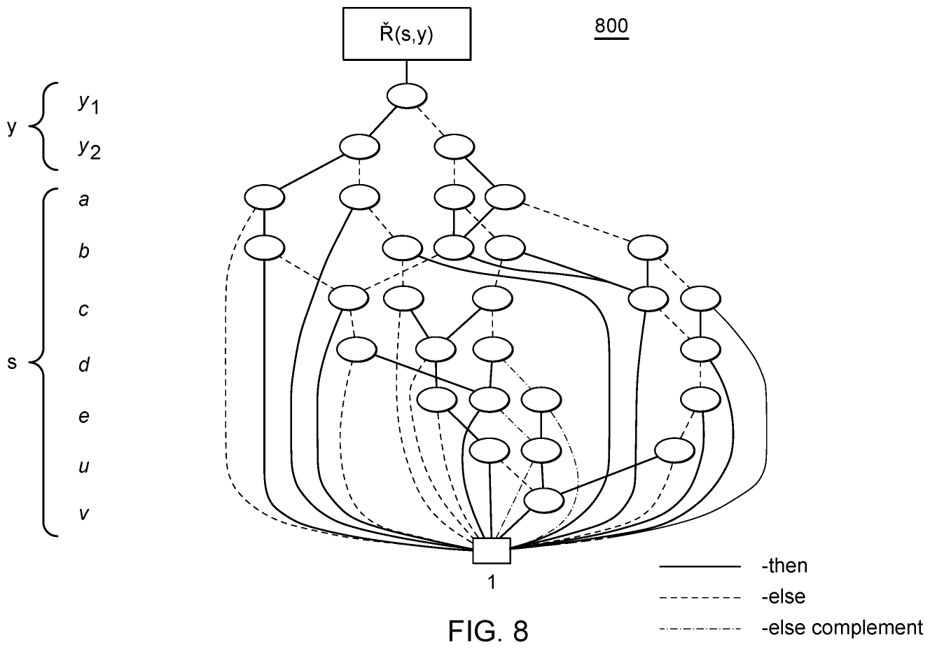

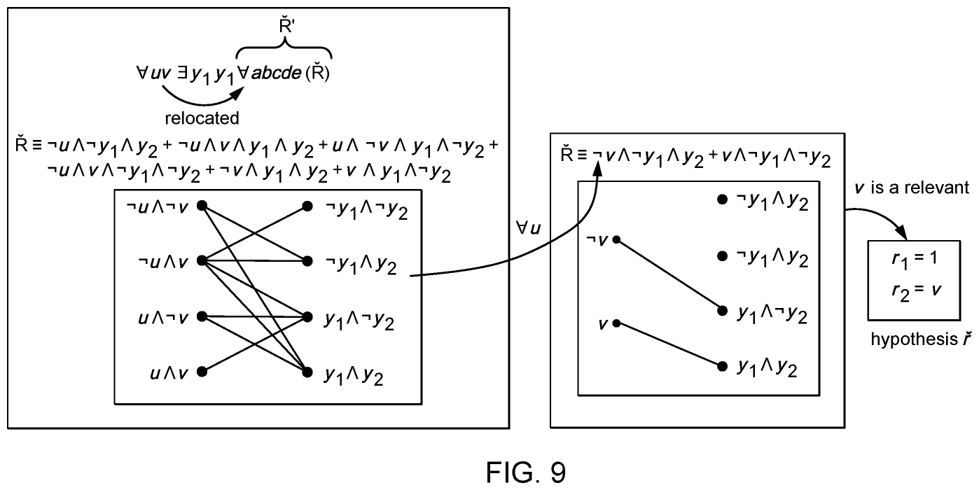

FIG. 8 shows an example binary decision tree or diagram 800 of the rectification candidates. As seen in FIG. 8, the binary decision tree or diagram 800 may be shown as a graph indicating logical relationships between the signal values and the values at the rectification points in the circuit design 502. The design device 208 may generate the binary decision tree or diagram 800 based on the Boolean representation. As seen in FIG. 9, the design device 208 analyzes the rectification candidates to determine a hypothesized change to the circuit design 502. Specifically, the design device 208 analyzes the Boolean representation to determine that the intermediate signal v is a relevant candidate for making a change. As seen in FIG. 5, v is an intermediate signal in the circuit design 502. As seen in FIG. 9, the hypothesized change is to make two changes represented by r₁ and r₂. r₁ is the change to be made to the rectification point y₁, and r₂ is the change to be made to the rectification point y₂. In the example of FIG. 9, the design device 208 hypothesizes that the rectification point y₁ should be connected to logic high and the rectification point y₂ should be connected to the signal V.

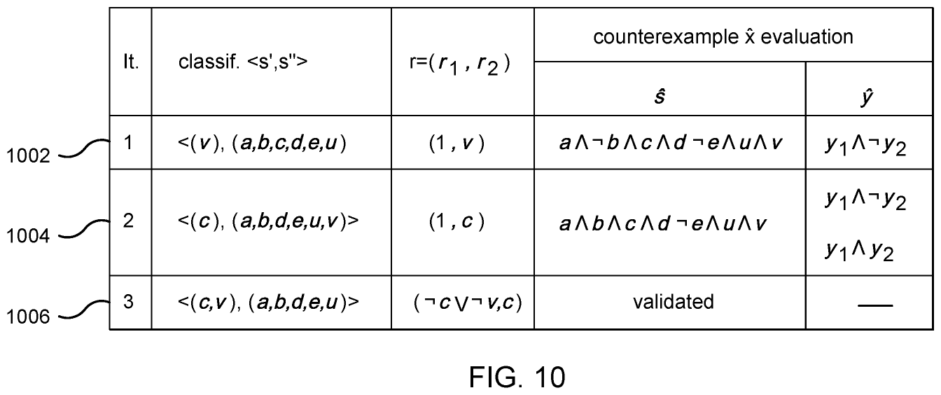

The design device 208 then makes the hypothesized change to the circuit design 502 and attempts to find counterexample inputs that cause the circuit design 502 with the hypothesized change to deviate from the revised specification 504. FIG. 10 illustrates a table that shows the counterexample inputs found by the design device 208. As seen in the row 1002, the design device 208 found a counterexample input for the hypothesized change identified in FIG. 9. As a result, the design device 208 understands that the hypothesized change shown in FIG. 9 is not the correct change to make to the circuit design 502. In response, the design device 208 updates the Boolean representation and analyzes the updated Boolean representation to determine a second hypothesized change. As seen in the row 1004, the design device 208 determines a second hypothesized change. According to the second hypothesized change, the rectification point y₁ is connected to logic high and the rectification point y₂ is connected to the input signal c. The design device 208 makes the second hypothesized change to the circuit design 502 and attempts to find counterexample inputs. As seen in FIG. 10, the design device 208 determines a counterexample input to that causes the circuit design 502 with the second hypothesized change to deviate from the revised specification 504. In response, the design device 208 updates the Boolean representation and hypothesizes another change.

The row labeled 1006 shows a third hypothesized change determined by the design device 208. In the third hypothesized change, the rectification point y₁ is connected to the logic OR of the inverse of c and v. The rectification point y₂ is connected to the input signal c. The design device 208 makes the hypothesized change in the circuit design 502 and attempts to find counterexample inputs that cause the circuit design 502 with the third hypothesized change to deviate from the revised specification 504. As seen in FIG. 10, the design device 208 finds no counterexample input. Because the design device 208 finds no counterexample input to the circuit design 502 with the third hypothesized change, the design device 208 determines that the third hypothesized change is the correct change to make to the circuit design 502 so that the circuit design 502 satisfies the new specification 504. The design device 208 then makes the change to the circuit design 502.

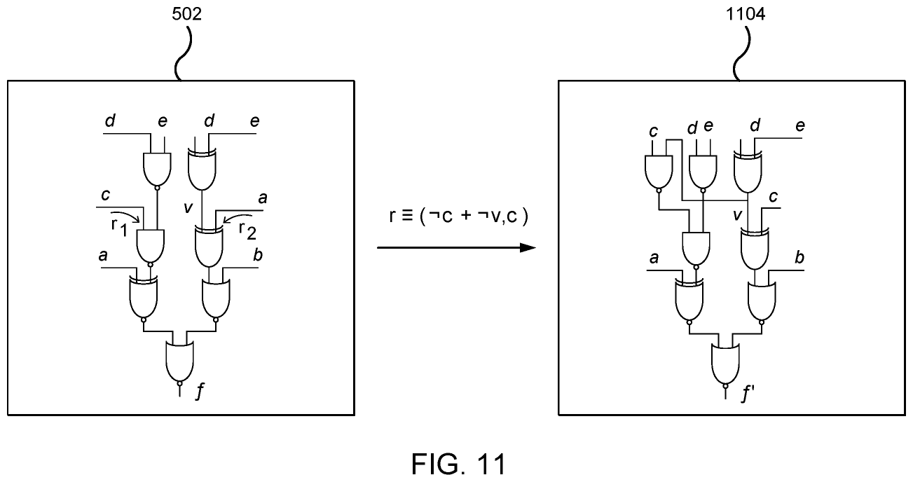

FIG. 11 shows the design device 208 making the third hypothesized change to the circuit design 502. As seen in FIG. 11, the design device 208 determines that the changes r₁ and r₂ should be made to the rectification points in the circuit design 502. The first change r₁ is to connect the first rectification point to the logical OR of the inverse of the signals c and v. Stated differently, the first change r₁ is to connect the input port of the gate at the rectification point y₁ to the logical NAND of c and v. In the updated circuit design 1104, the rectification point y₁ has been connected to the logical NAND of c and v. Additionally, the design device 208 determines that the second change r₂ is to connect the input port of the gate at the rectification point y₂ to the signal c. As seen in FIG. 11, the updated circuit design 1104 has the rectification point y₂ connected to the signal c. In this manner, the design device 208 determines and makes the changes to the circuit design 502 so that the circuit design 502 satisfies the revised specification 504.

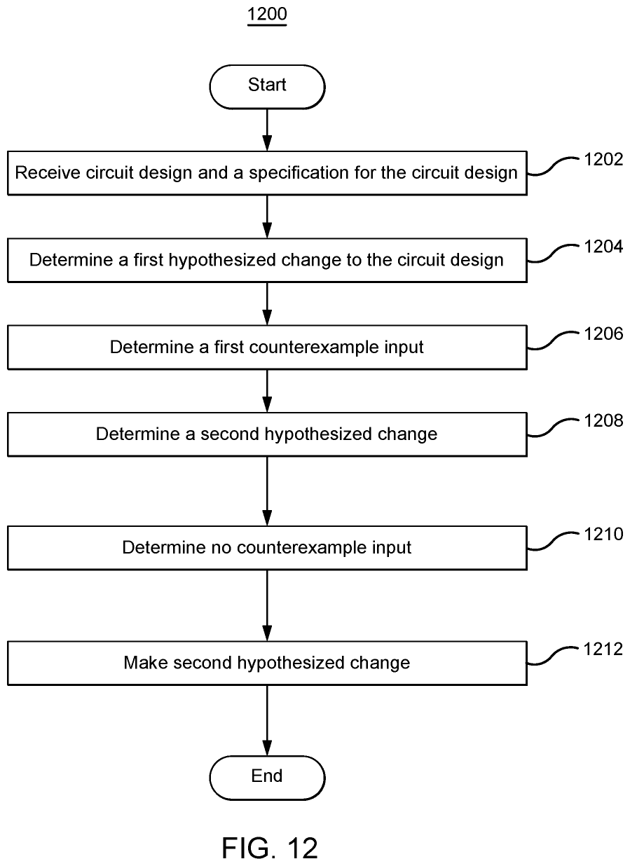

FIG. 12 is a flow chart of an example method 1200 performed in the system 200 of FIG. 2. In particular embodiments, the design device 208 performs the method 1200. By performing the method 1200, the design device 208 uses a reinforced learning loop to determine a change to a circuit design 214 so that the circuit design 214 satisfies a revised specification 216.

In block 1202, the design device 208 receives the circuit design 214 and a revised specification 216. The design device 208 uses a reinforced learning loop to determine a change 218 to be made to the circuit design 214 such that the circuit design 214 satisfies the specification 216.

In block 1204, the design device 208 determines a first hypothesized change to the circuit design 214. In certain embodiments, the design device 208 analyzes the circuit design 214 and the revised specification 216, including input samples and rectification points to generate a Boolean representation that may indicate a hypothesis space. The design device 208 then analyzes the Boolean representation or the hypothesis space to generate the first hypothesized change.

In block 1206, the design device 208 determines a first counterexample input for the first hypothesized change. The first counterexample input may be an input that causes the circuit design 214 with the first hypothesized change to not satisfy or deviate from the specification 216. Stated differently, the first counterexample input may be an input that shows or demonstrates that the first hypothesized change does not cause the circuit design 214 to satisfy or comply with the specification 216.

In block 1208, the design device 208 determines a second hypothesized change. For example, the design device 208 may recompute or update the Boolean representation or the hypothesis space after determining the first counterexample input. The design device 208 may update the Boolean representation and the hypothesis space after analyzing the first hypothesized change and the first counterexample input. During the update, the design device 208 may eliminate certain hypotheses from the hypothesis space that the design device 208 determines will not cause the circuit design 214 to satisfy the specification 216.

In block 1210, the design device 208 determines that there are no counterexample inputs when the second hypothesized change is made to the circuit design 214. Stated differently, the design device 208 may determine that there are no counterexample inputs that cause the circuit design 214 with the second hypothesized change to deviate from or not satisfy the specification 216. As a result, the design device 208 may determine that the second hypothesized change should be made to the circuit design 214 so that the circuit design 214 complies with or satisfies the specification 216. In block 1212, the design device 208 makes the second hypothesized change to the circuit design 214 to produce the changed circuit design 220.

In some embodiments, the design device 208 addresses or solves the design rectification problem using quantified Boolean logic, which may provide sound and complete capture of the update choices for the rectification. The design device 208 provides an analytical search for small patches that maximize logic sharing in the implementation logic. The use of reinforced learning that identifies relevant signals allows scalable search for a compact rectification.

The design device 208 may search for a vector of pins (y₁, . . . , yₘ) in the circuit design 214 and change their functions so that the changed circuit design 220 implements the revised specification 216. The search may examine individual pin subsets that divide the problem into independently solved tasks. For a revised specification 216 with a function vector f′ and fixed implementation h, the rectification function r is determined from the consistency of the equation h(r)=f′. For all input signals x, h(r(x))=f′(x). h(r(x))=f′(x) may be represented as ψ(r). Solving ψ for r is considered using Boolean functional synthesis.

For a revised specification 216 with a function vector f′ and a given function r≡(r₁(x), . . . , rₘ(x)), the existence of a solution for f′=h(r) may be determined using reasoning over a Boolean function interval.

Let r≡(r₁(x)=y₁ . . . (rₘ(x)=yₘ). The solution exists if and only if H≡[f′∧r, f′∨¬r] is not empty. Then, for any h∈H, the equation f′=h(r) holds. When h is fixed, the validity of a given rectification r is predicated on the interval's containment of h:

ψ(r)≡h∈[f′∧r, f′∨¬r]≡L≤h≤U≡¬L∧¬h∨h∧U=r→(h=f′);

where L=f′∧r and U=f′∨¬r.

Unlike conventional systems, the design device 208 may allow internal signals of the circuit design 214 to be candidate patch inputs. The existence of r(s) is stated as extending the previously formulation for Boolean function synthesis. The input/output semantics of candidate patch input functions t≡(t₁, . . . , tₖ) is t(x, s)≡(t₁(x)=s₁) . . . (tₘ(x)=sₖ). The existence of rectification then follows from the validity of ∀s∃y∀x(t→(h=f′)), where ∀s∃y may be the totality constrain on rectification choices and t→(h=f′) is denoted as φ(x, s, y). The new t replaces r in ψ. The additional outer quantifiers ∀∃ enforce totality on the rectification function.

When the totality constrain ∀s∃y is dropped, the open formula variant R(s, y)≡∀xφ(x, s, y) interprets the behavior of x variables in the domain of s. The elimination of x encapsulates rectification choices in the form of Boolean function synthesis: ∀s∃yR(s, y) (relocated sᵢ∈s). The rectification choices are captured for multiple rectification points in the closed form, which may yield completeness when more than one rectification point is given. The derived Boolean relation φ′ may give a complete capture of the updates. A total deterministic relation of r(s, y) compatible ( [symbol] ) with R(s, y) may offer a rectification candidate.

A rectification constructor goal may be to select r(s, y) that reduces signal dependence. A rectification function r(s′, y) for which a signal sᵢ is irrelevant exists if and only if ∀s′∃y∀sᵢ [symbol] (s, y) remains true. A feasible forward hop of sᵢ over ∃y may imply the existence of rectification that does not depend on sᵢ. It may be posed as a search that classifies signals into relevant and irrelevant (e.g., not unique): Find a partition [symbol] s′, s″ [symbol] of variables s for which relocation of s″ variables ∀s′∃y∀s″ [symbol] (s′, s″, y) (relocated s″⊆s) keeps the formula true while maximizing the size of s″.

The design device 208 may provide a symbolic sampling formulation that addresses scalability of computations. For example, in the process 400 of FIG. 4, the design device 208 may construct φ and derive [symbol] in block 402. Additionally, in block 404, the design device 208 may abstract irrelevant signals in [symbol] . In block 406, the design device 208 may solve ř¬φ(environment). In block 408, the design device 208 may compute a concretized [symbol] .

In certain embodiments, the design device 208 provides search completeness at multiple rectification points, which offers solutions that are not reproducible by an approach that relies on examining individual points one at a time.

In summary, a system 200 determines the incremental changes to a circuit design 214 to satisfy a new or revised specification 216. Generally, the system 100 uses a reinforced learning loop to generate hypothesized changes to the circuit design 214. These hypotheses are then proven or disproven through discovery of counterexample inputs that would cause the circuit design 214 with the hypothesized changes to not satisfy the new or revised specification 216. These counterexamples are then used in the learning loop to refine the hypotheses until the learning loop produces a hypothesis with no counterexample inputs. This hypothesis is then determined to be the incremental update to the circuit design 214 and is made to the circuit design 214 such that the circuit design 214 satisfies the new or revised specification 216.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.”

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), crasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

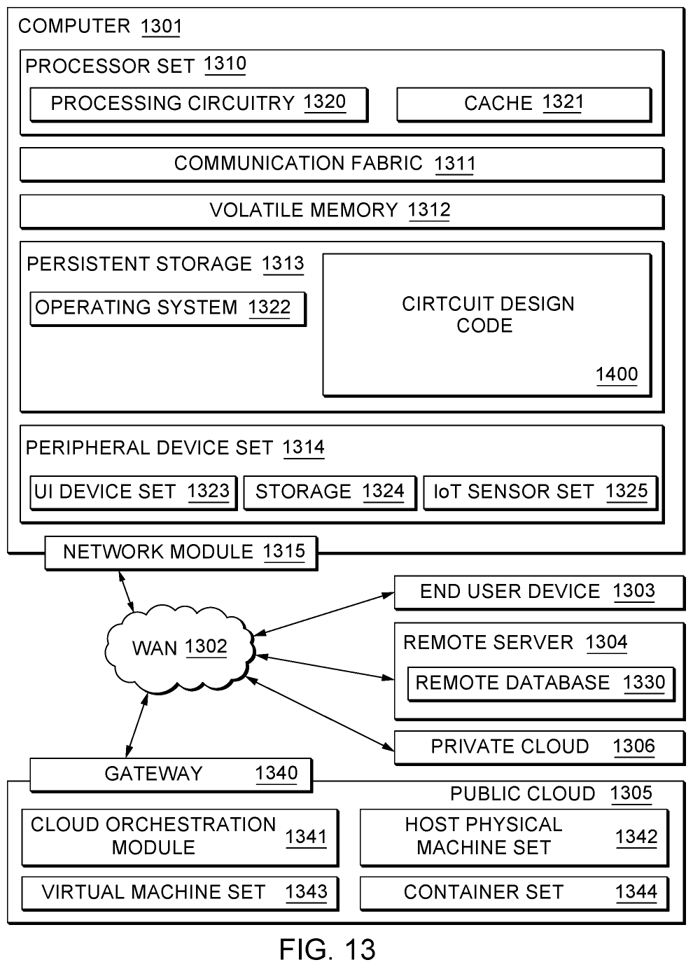

FIG. 13 illustrates an example computing environment 1300. The computing environment 1300 contains an example of an environment for the execution of at least some of the computer code involved in performing the inventive methods, such as circuit design code block 1400. In addition to block 1400, computing environment 1300 includes, for example, computer 1301, wide area network (WAN) 1302, end user device (EUD) 1303, remote server 1304, public cloud 1305, and private cloud 1306. In this embodiment, computer 1301 includes processor set 1310 (including processing circuitry 1320 and cache 1321), communication fabric 1311, volatile memory 1312, persistent storage 1313 (including operating system 1322 and block 1400, as identified above), peripheral device set 1314 (including user interface (UI) device set 1323, storage 1324, and Internet of Things (IOT) sensor set 1325), and network module 1315. Remote server 1304 includes remote database 1330. Public cloud 1305 includes gateway 1340, cloud orchestration module 1341, host physical machine set 1342, virtual machine set 1343, and container set 1344.

COMPUTER 1301 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1330. As is well understood in the art of computer technology, and depending upon the technology, performance of a computer-implemented method may be distributed among multiple computers and/or between multiple locations. On the other hand, in this presentation of computing environment 1300, detailed discussion is focused on a single computer, specifically computer 1301, to keep the presentation as simple as possible. Computer 1301 may be located in a cloud, even though it is not shown in a cloud in FIG. 13. On the other hand, computer 1301 is not required to be in a cloud except to any extent as may be affirmatively indicated.

PROCESSOR SET 1310 includes one, or more, computer processors of any type now known or to be developed in the future. Processing circuitry 1320 may be distributed over multiple packages, for example, multiple, coordinated integrated circuit chips. Processing circuitry 1320 may implement multiple processor threads and/or multiple processor cores. Cache 1321 is memory that is located in the processor chip package(s) and is typically used for data or code that should be available for rapid access by the threads or cores running on processor set 1310. Cache memories are typically organized into multiple levels depending upon relative proximity to the processing circuitry. Alternatively, some, or all, of the cache for the processor set may be located “off chip.” In some computing environments, processor set 1310 may be designed for working with qubits and performing quantum computing.

Computer readable program instructions are typically loaded onto computer 1301 to cause a series of operational steps to be performed by processor set 1310 of computer 1301 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1321 and the other storage media discussed below. The program instructions, and associated data, are accessed by processor set 1310 to control and direct performance of the inventive methods. In computing environment 1300, at least some of the instructions for performing the inventive methods may be stored in block 1400 in persistent storage 1313.

COMMUNICATION FABRIC 1311 is the signal conduction path that allows the various components of computer 1301 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 1312 is any type of volatile memory now known or to be developed in the future. Examples include dynamic type random access memory (RAM) or static type RAM. Typically, volatile memory 1312 is characterized by random access, but this is not required unless affirmatively indicated. In computer 1301, the volatile memory 1312 is located in a single package and is internal to computer 1301, but, alternatively or additionally, the volatile memory may be distributed over multiple packages and/or located externally with respect to computer 1301.

PERSISTENT STORAGE 1313 is any form of non-volatile storage for computers that is now known or to be developed in the future. The non-volatility of this storage means that the stored data is maintained regardless of whether power is being supplied to computer 1301 and/or directly to persistent storage 1313. Persistent storage 1313 may be a read only memory (ROM), but typically at least a portion of the persistent storage allows writing of data, deletion of data and re-writing of data. Some familiar forms of persistent storage include magnetic disks and solid state storage devices. Operating system 1322 may take several forms, such as various known proprietary operating systems or open source Portable Operating System Interface-type operating systems that employ a kernel. The code included in block 1400 typically includes at least some of the computer code involved in performing the inventive methods.

PERIPHERAL DEVICE SET 1314 includes the set of peripheral devices of computer 1301. Data communication connections between the peripheral devices and the other components of computer 1301 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 1323 may include components such as a display screen, speaker, microphone, wearable devices (such as goggles and smart watches), keyboard, mouse, printer, touchpad, game controllers, and haptic devices. Storage 1324 is external storage, such as an external hard drive, or insertable storage, such as an SD card. Storage 1324 may be persistent and/or volatile. In some embodiments, storage 1324 may take the form of a quantum computing storage device for storing data in the form of qubits. In embodiments where computer 1301 is required to have a large amount of storage (for example, where computer 1301 locally stores and manages a large database) then this storage may be provided by peripheral storage devices designed for storing very large amounts of data, such as a storage area network (SAN) that is shared by multiple, geographically distributed computers. IoT sensor set 1325 is made up of sensors that can be used in Internet of Things applications. For example, one sensor may be a thermometer and another sensor may be a motion detector.

NETWORK MODULE 1315 is the collection of computer software, hardware, and firmware that allows computer 1301 to communicate with other computers through WAN 1302. Network module 1315 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1315 are performed on the same physical hardware device. In other embodiments (for example, embodiments that utilize software-defined networking (SDN)), the control functions and the forwarding functions of network module 1315 are performed on physically separate devices, such that the control functions manage several different network hardware devices. Computer readable program instructions for performing the inventive methods can typically be downloaded to computer 1301 from an external computer or external storage device through a network adapter card or network interface included in network module 1315.

WAN 1302 is any wide area network (for example, the internet) capable of communicating computer data over non-local distances by any technology for communicating computer data, now known or to be developed in the future. In some embodiments, the WAN 1302 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1303 is any computer system that is used and controlled by an end user (for example, a customer of an enterprise that operates computer 1301), and may take any of the forms discussed above in connection with computer 1301. EUD 1303 typically receives helpful and useful data from the operations of computer 1301. For example, in a hypothetical case where computer 1301 is designed to provide a recommendation to an end user, this recommendation would typically be communicated from network module 1315 of computer 1301 through WAN 1302 to EUD 1303. In this way, EUD 1303 can display, or otherwise present, the recommendation to an end user. In some embodiments, EUD 1303 may be a client device, such as thin client, heavy client, mainframe computer, desktop computer and so on.

REMOTE SERVER 1304 is any computer system that serves at least some data and/or functionality to computer 1301. Remote server 1304 may be controlled and used by the same entity that operates computer 1301. Remote server 1304 represents the machine(s) that collect and store helpful and useful data for use by other computers, such as computer 1301. For example, in a hypothetical case where computer 1301 is designed and programmed to provide a recommendation based on historical data, then this historical data may be provided to computer 1301 from remote database 1330 of remote server 1304.

PUBLIC CLOUD 1305 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 1305 is performed by the computer hardware and/or software of cloud orchestration module 1341. The computing resources provided by public cloud 1305 are typically implemented by virtual computing environments that run on various computers making up the computers of host physical machine set 1342, which is the universe of physical computers in and/or available to public cloud 1305. The virtual computing environments (VCEs) typically take the form of virtual machines from virtual machine set 1343 and/or containers from container set 1344. It is understood that these VCEs may be stored as images and may be transferred among and between the various physical machine hosts, either as images or after instantiation of the VCE. Cloud orchestration module 1341 manages the transfer and storage of images, deploys new instantiations of VCEs and manages active instantiations of VCE deployments. Gateway 1340 is the collection of computer software, hardware, and firmware that allows public cloud 1305 to communicate through WAN 1302.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1306 is similar to public cloud 1305, except that the computing resources are only available for use by a single enterprise. While private cloud 1306 is depicted as being in communication with WAN 1302, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1305 and private cloud 1306 are both part of a larger hybrid cloud.

While the foregoing is directed to embodiments of the present invention, other and further embodiments of the invention may be devised without departing from the basic scope thereof, and the scope thereof is determined by the claims that follow.

What is claimed is:

1. A method comprising:
receiving a circuit design and a specification for the circuit design;
determining a first hypothesized change to the circuit design based at least in part on the circuit design and the specification, wherein making the first hypothesized change to the circuit design produces a first changed circuit design;
determining a first counterexample input that causes the first changed circuit design to produce an output that departs from the specification;
determining a second hypothesized change to the circuit design based at least in part on the first hypothesized change, wherein making the second hypothesized change to the circuit design produces a second changed circuit design; and
in response to determining that the second changed circuit design has no counterexample input that causes the second changed circuit design to produce an output that departs from the specification, making the second hypothesized change to the circuit design.

2. The method of claim 1, wherein determining the first hypothesized change comprises determining input values for the circuit design that cause the circuit design to produce an output that departs from the specification.

3. The method of claim 2, wherein determining the first hypothesized change further comprises transforming the input values to a Boolean representation.

4. The method of claim 3, wherein the Boolean representation of the input values comprises a Boolean formula.

5. The method of claim 3, wherein determining the first counterexample input comprises generating a binary decision diagram based on the Boolean representation of the input values.

6. The method of claim 1, wherein making the second hypothesized change comprises changing a connection to an input port of the circuit design.

7. The method of claim 6, wherein the input port is specified prior to determining the first hypothesized change.

8. A system comprising:
a memory; and
a processor communicatively coupled to the memory, the processor configured to:
receive a circuit design and a specification for the circuit design;
determine a first hypothesized change to the circuit design based at least in part on the circuit design and the specification, wherein making the first hypothesized change to the circuit design produces a first changed circuit design;
determine a first counterexample input that causes the first changed circuit design to produce an output that departs from the specification;
determine a second hypothesized change to the circuit design based at least in part on the first hypothesized change, wherein making the second hypothesized change to the circuit design produces a second changed circuit design; and
in response to determining that the second changed circuit design has no counterexample input that causes the second changed circuit design to produce an output that departs from the specification, make the second hypothesized change to the circuit design.

9. The system of claim 8, wherein determining the first hypothesized change comprises determining input values for the circuit design that causes the circuit design to produce an output that departs from the specification.

10. The system of claim 9, wherein determining the first hypothesized change further comprises transforming the input values to a Boolean representation.

11. The system of claim 10, wherein the Boolean representation of the input values comprises a Boolean formula.

12. The system of claim 10, wherein determining the first counterexample input comprises generating a binary decision diagram based on the Boolean representation of the input values.

13. The system of claim 8, wherein making the second hypothesized change comprises changing a connection to an input port of the circuit design.

14. The system of claim 13, wherein the input port is specified prior to determining the first hypothesized change.

15. A non-transitory computer readable medium storing instructions that, when executed by a processor, cause the processor to:
determine a first hypothesized change to a circuit design based at least in part on the circuit design and a specification for the circuit design;
determine a first counterexample input that causes the circuit design with the first hypothesized change to depart from the specification;
in response to determining the first counterexample, determine a second hypothesized change to the circuit design based at least in part on the first hypothesized change; and
in response to determining that there is no counterexample input that causes the circuit design with the second hypothesized change to depart from the specification, make the second hypothesized change to the circuit design.

16. The medium of claim 15, wherein determining the first hypothesized change comprises determining input values for the circuit design that causes the circuit design to produce an output that departs from the specification.

17. The medium of claim 16, wherein determining the first hypothesized change further comprises transforming the input values to a Boolean representation.

18. The medium of claim 17, wherein the Boolean representation of the input values comprises a Boolean formula.

19. The medium of claim 17, wherein determining the first counterexample input comprises generating a binary decision diagram based on the Boolean representation of the input vector.

20. The medium of claim 15, wherein making the second hypothesized change comprises changing a connection to an input port of the circuit design.
